(19) United States
(12) Patent Application Publication
(10) Pub. No.: US 2024/0363685 A1
(43) Pub. Date: Oct. 31, 2024

(54) SEMICONDUCTOR DEVICE

(71) Applicant: SAMSUNG ELECTRONICS CO., LTD., Suwon-si (KR)

(72) Inventors: Hyun Jun LIM, Suwon-si (KR); Tae Ho CHA, Suwon-si (KR); Su Bin LEE, Suwon-si (KR); Jeong Hyeon LEE, Suwon-si (KR); Hak Jong LEE, Suwon-si (KR); Seung Hyeon HONG, Suwon-si (KR)

(73) Assignee: SAMSUNG ELECTRONICS CO., LTD., Suwon-si (KR)

(21) Appl. No.: 18/507,839

(22) Filed: Nov. 13, 2023

(30) Foreign Application Priority Data
Apr. 27, 2023 (KR) 10-2023-0055194

(51) Int. Cl. H01L 29/06; H01L 29/08; H01L 29/423; H01L 29/66; H01L 29/775; H01L 29/786

(52) U.S. Cl. CPC H01L 29/0673; H01L 29/0847; H01L 29/42392; H01L 29/66545; H01L 29/775; H01L 29/78696

(57) ABSTRACT

A semiconductor device includes: an active pattern including a lower pattern and sheet patterns spaced apart from the lower pattern in a first direction; gate structures being separate in a second direction on the lower pattern. The gate structure includes a gate electrode and a gate insulating layer; a source/drain recess between the gate structures adjacent to each other; and a source/drain pattern filling the source/drain recess. The source/drain pattern includes: a first epitaxial region extended along a sidewall and a bottom surface of the source/drain recess, a second epitaxial region on the first epitaxial insertion epitaxial regions that are in contact with the first epitaxial region. The respective insertion epitaxial regions are spaced apart from each other and include silicon germanium. The first epitaxial region is disposed between the second epitaxial region and the insertion epitaxial region.

### CROSS-REFERENCE TO RELATED APPLICATION

This application is based on and claims priority under 35 U.S.C. § 119 to Korean Patent Application No. 10-2023-0055194, filed on Apr. 27, 2023, in the Korean Intellectual Property Office, the disclosure of which is incorporated by reference herein in its entirety.

### BACKGROUND

### 1. Field

The disclosure relates to a semiconductor device, and more particularly, to a semiconductor device that includes a multi-bridge channel field effect transistor (MBCFET™).

### 2. Description of Related Art

As one of scaling techniques for increasing a density of a semiconductor device, a multi-gate transistor for forming a multi-channel active pattern (or silicon body) of a fin or nanowire shape on a substrate and for forming a gate on a surface of the multi-channel active pattern has been suggested.

Since this multi-gate transistor uses a three-dimensional channel, it is easy to scale the multi-gate transistor. Also, even though a gate length of the multi-gate transistor is not increased, a current control capability may be improved. In addition, a short channel effect (SCE) in which a potential of a channel region is affected by a drain voltage may be suppressed effectively.

### SUMMARY

Provided is a semiconductor device capable of improving element performance and reliability.

Provided is a method for fabricating a semiconductor device, which is capable of improving element performance and reliability.

According to one aspect of the disclosure, a semiconductor device includes: an active pattern including a lower pattern and a plurality of sheet patterns spaced apart from the lower pattern in a first direction: a plurality of gate structures being spaced apart from each other in a second direction on the lower pattern, wherein each of the plurality of gate structures includes a gate electrode and a gate insulating layer: a source/drain recess between the gate structures adjacent to each other; and a source/drain pattern filling the source/drain recess. The source/drain pattern includes: a first epitaxial region extended along a sidewall and a bottom surface of the source/drain recess, a second epitaxial region on the first epitaxial region, and a plurality of insertion epitaxial regions that are in contact with the first epitaxial region, wherein the respective insertion epitaxial regions are spaced apart from each other and include silicon germanium, and wherein the first epitaxial region is disposed between the second epitaxial region and the insertion epitaxial region.

According to another aspect of the disclosure, a semiconductor device includes: an active pattern including a lower pattern and a plurality of sheet patterns spaced apart from the lower pattern in a first direction: a plurality of gate structures being spaced apart from each other in a second direction on the lower pattern, wherein each of the plurality of gate structures includes a gate electrode and a gate insulating layer; a source/drain recess between the gate structures adjacent to each other; and a source/drain pattern filling the source/drain recess, wherein the gate structure includes an inner gate structure between the lower pattern and the sheet pattern and between the sheet patterns adjacent to each other, wherein the source/drain pattern includes: a plurality of insertion epitaxial regions, and a first epitaxial region that is in contact with each of the insertion epitaxial regions and is extended along a sidewall and a bottom surface of the source/drain recess, and wherein the plurality of insertion epitaxial regions are disposed between the lower pattern and the sheet pattern and between the sheet patterns adjacent to each other in the first direction and are in contact with the gate insulating layer of the inner gate structure.

According to another aspect of the disclosure, a semiconductor device includes: an active pattern including a lower pattern and a plurality of sheet patterns spaced apart from the lower pattern in a first direction: a plurality of gate structures being spaced apart from each other in a second direction on the lower pattern, wherein each of the plurality of gate structures includes a gate electrode and a gate insulating layer; a source/drain recess between the gate structures adjacent to each other, wherein the source/drain recess includes a plurality of width extension regions: and a source/drain pattern filling the source/drain recess, wherein the gate structure includes an inner gate structure disposed between the lower pattern and the sheet pattern and between the sheet patterns adjacent to each other, wherein a width of each of the width extension regions in the first direction is increased and then reduced as each of the width extension regions becomes far away from an upper surface of the lower pattern, wherein a point at which a width of the width extension region in a second direction is maximum is positioned between the lower pattern and the sheet pattern and between the sheet patterns adjacent to each other in the first direction, wherein the source/drain pattern includes: a plurality of insertion epitaxial regions that are in contact with the gate insulating layer of the inner gate structure and include silicon germanium doped with arsenic (As), a first epitaxial region that is in contact with each of the insertion epitaxial regions and each of the sheet patterns, including silicon, and a second epitaxial region disposed on the first epitaxial region, including silicon doped with phosphorus (P).

The embodiments of the disclosure are not limited to those mentioned above and additional objects of the present disclosure, which are not mentioned herein, will be clearly understood by those skilled in the art from the following description of the disclosure.

### BRIEF DESCRIPTION OF DRAWINGS

The above and other aspects and features of the present disclosure will become more apparent by describing in detail example embodiments thereof with reference to the attached drawings, in which:

FIG. 1 illustrates a semiconductor device according to some embodiments;

FIG. 2 is a cross-sectional view taken along the line A-A of FIG. 1;

FIG. 3 is a cross-sectional view taken along the line B-B of FIG. 1;

FIG. 4 illustrates a shape of a first sheet pattern of FIG. 2;

FIG. 5 illustrates a plan view taken along line C-C of FIG. 2;

FIG. 6 illustrates an enlarged view of a portion P of FIG. 2;

FIG. 7 illustrates a germanium fraction of a first source/drain pattern;

FIGS. 8 to 11 illustrate a semiconductor memory device according to some embodiments;

FIGS. 12 and 13 illustrate a semiconductor memory device according to some embodiments;

FIGS. 14 and 15 illustrate a semiconductor device according to some embodiments;

FIGS. 16 and 17 illustrate a semiconductor device according to some embodiments;

FIGS. 18 and 19 illustrate a semiconductor device according to some embodiments.

FIGS. 20 and 21 illustrate a semiconductor memory device according to some embodiments: and

FIGS. 22 to 28 illustrate intermediate steps to describe a method for fabricating a semiconductor memory device according to some embodiments.

### DETAILED DESCRIPTION

The embodiments described herein are non-limiting example embodiments, and thus, the disclosure is not limited thereto and may be realized in various other forms.

It will be understood that, although the terms “first”, “second”, etc. may be used herein to describe various elements or components, these elements or components should not be limited by these terms. These terms are only used to distinguish one element or component from another element or component. Therefore, a first element or component discussed below could be termed a second element or component without departing from the technical spirits of the present disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “include” and “comprise”, and the derivatives thereof refer to inclusion without limitation. The term “or” is an inclusive term meaning “and/or”. The phrase “associated with,” as well as derivatives thereof, refer to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of A, B, and C” includes any of the following combinations: A, B, C, A and B, A and C, B and C, and A and B and C, and any variations thereof. Similarly, the term “set” means one or more. Accordingly, the set of items may be a single item or a collection of two or more items.

As shown in the disclosure, a semiconductor device according to some embodiments includes a tunneling transistor (tunneling field-effect transistor (FET)), a three-dimensional (3D) transistor, or a two-dimensional (2D) material based FETs, and a heterostructure thereof. Also, the semiconductor device according to some embodiments may include a bipolar junction transistor or a laterally diffused metal oxide semiconductor (LDMOS) transistor.

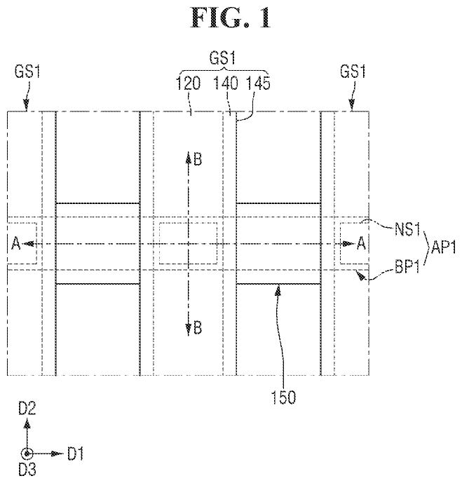

The semiconductor device according to some embodiments will be described with reference to FIGS. 1 to 7.

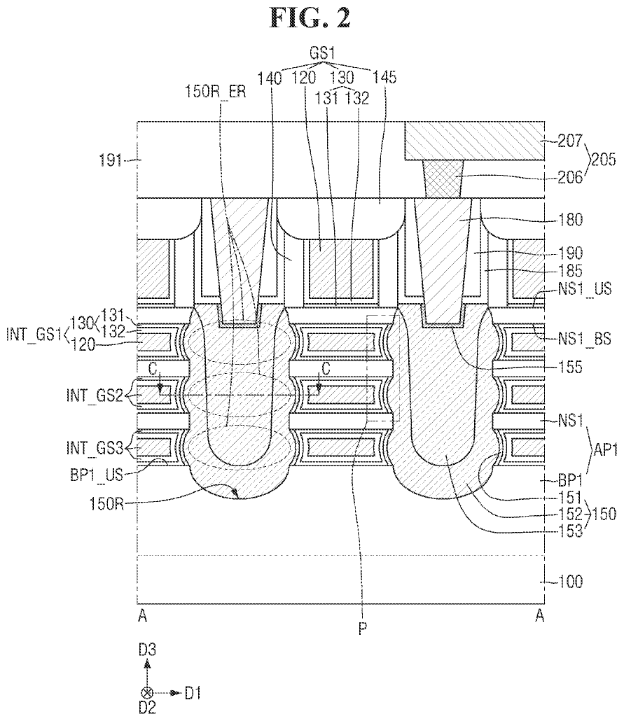

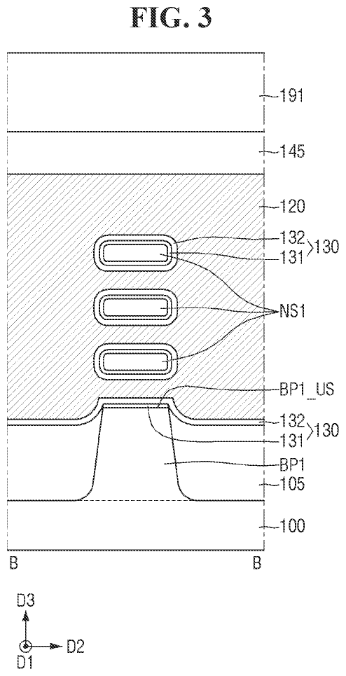

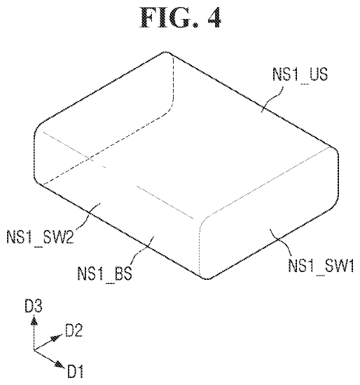

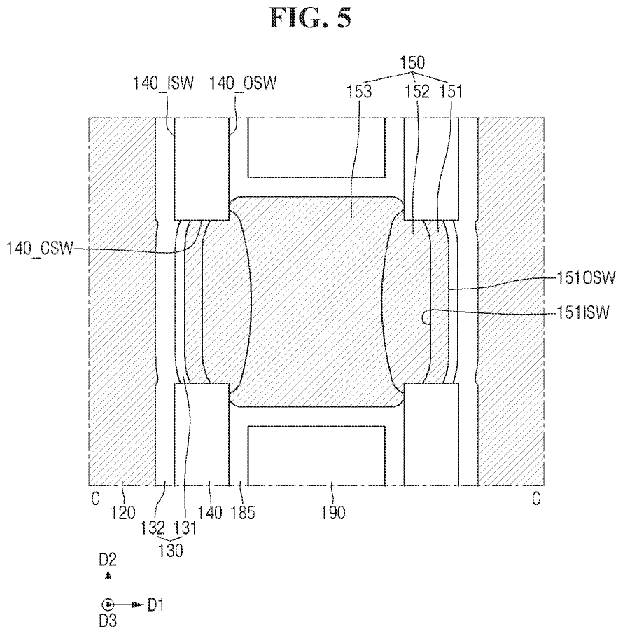

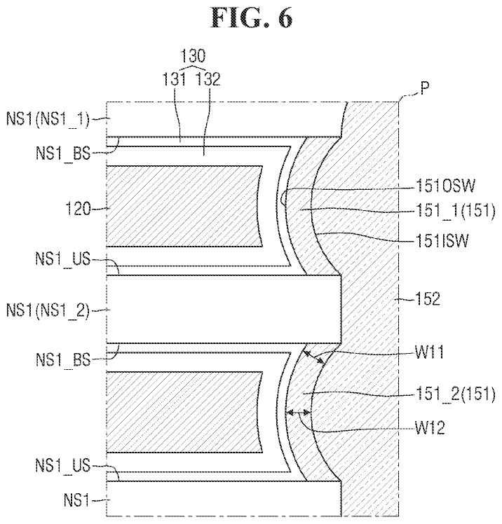

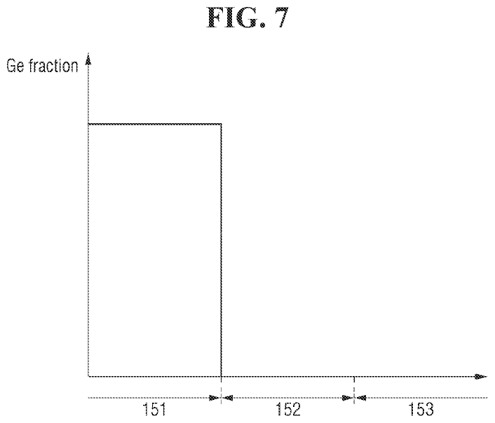

FIG. 1 is an example plan view illustrating a semiconductor device according to some embodiments. FIG. 2 is a cross-sectional view taken along the line A-A of FIG. 1. FIG. 3 is a cross-sectional view taken along the line B-B of FIG. 1. FIG. 4 is a view illustrating a shape of a first sheet pattern of FIG. 2. FIG. 5 is a plan view taken along line C-C of FIG. 2. FIG. 6 is an enlarged view of a portion P of FIG. 2. FIG. 7 is a view illustrating a germanium fraction of a first source/drain pattern. Components of FIG. 1, except for a first gate insulating layer 130, a source/drain etch stop layer 185 and a wiring structure 205, are shown.

Referring to FIGS. 1 to 7, the semiconductor device according to some embodiments may include a first active pattern AP1, a plurality of first gate electrodes 120 and a first source/drain pattern 150.

In one embodiment, the substrate 100 may be a bulk silicon or a silicon-on-insulator (SOI). In one embodiment, the substrate 100 may be a silicon substrate, or may include another material, for example, silicon germanium, silicon germanium on insulator (SGOI), indium antimonide, lead telluride, indium arsenide, indium phosphide, gallium arsenide, or gallium antimonide, but is not limited thereto.

A first active pattern AP1 may be disposed on the substrate 100. The first active pattern AP1 may be extended to be along in a first direction D1. In one embodiment, the first active pattern AP1 may be disposed in a region in which an n-channel metal-oxide semiconductor (NMOS) is formed.

In one embodiment, the first active pattern AP1 (shown in FIGS. 1 and 2) may be a multi-channel active pattern. The first active pattern AP1 may include a first lower pattern BP1 and a plurality of first sheet patterns NS1.

The first lower pattern BP1 (shown in FIG. 1) may be protruded from the substrate 100. The first lower pattern BP1 may be extended to be along in the first direction D1. The first lower pattern BP1 may be a fin-type pattern.

The plurality of first sheet patterns NS1 (shown in FIGS. 1 and 2) may be disposed on an upper surface BP1_US (shown in FIG. 2) of the first lower pattern. The plurality of first sheet patterns NS1 may be spaced apart from the first lower pattern BP1 in a third direction D3. Each of the first sheet patterns NS1 may be spaced apart from each other in the third direction D3.

Each first sheet pattern NS1 (shown in FIGS. 1 and 2) may include an upper surface NS1_US (shown in FIG. 2) and a bottom surface NS1_BS (shown in FIG. 2). The upper surface NS1_US of the first sheet pattern is a surface opposite to the bottom surface NS1_BS of the first sheet pattern in the third direction D3. Each of the first sheet patterns NS1 may include first sidewalls NS1_SW1 (as shown in FIG. 4) opposite to each other in the first direction D1 and second sidewalls NS1_SW2 (as shown in FIG. 4) opposite to each other in a second direction D2. The third direction D3 may be a direction crossing the first direction D1 and the second direction D2. In one embodiment, the third direction D3 may be a thickness direction of the substrate 100. The first direction D1 may be a direction crossing the second direction D2.

The upper surface NS1_US (shown in FIG. 2) of the first sheet pattern and the bottom surface NS1_BS (shown in FIG. 2) of the first sheet pattern may be connected to each other by the first sidewall NS1_SW1 of the first sheet pattern and the second sidewall NS1_SW2 of the first sheet pattern. The first sidewall NS1_SW1 of the first sheet pattern is connected to the first source/drain pattern 150, which will be described later, and is in contact with the first source/drain pattern 150. The first sidewall NS1_SW1 of the first sheet pattern may include a longitudinal end of the first sheet pattern NS1.

Three first sheet pattern NS1 are shown as being disposed in the third direction D3, but are only for convenience of description, and the present disclosure is not limited thereto.

The first lower pattern BP1 (shown in FIGS. 1 to 3) may be formed by etching a portion of the substrate 100, or may include an epitaxial layer grown from the substrate 100. The first lower pattern BP1 may include silicon or germanium, which is an elemental semiconductor material. In addition, the first lower pattern BP1 may include a compound semiconductor, and may include, for example, a Group IV-IV compound semiconductor or a Group III-V compound semiconductor.

The group IV-IV compound semiconductor may be a binary compound or ternary compound, which includes at least two of carbon (C), silicon (Si), germanium (Ge) or tin (Sn), or a compound including at least two of carbon (C), silicon (Si), germanium (Ge) or tin (Sn), which are doped with a group IV element.

In one embodiment, the group III-V compound semiconductor may be one of a binary compound, a ternary compound or a quaternary compound, which is formed by combination of at least one of aluminum (Al), gallium (Ga) or indium (In), which is a group III element, and one of phosphorus (P), arsenic (As) and antimony (Sb), which are group V elements.

The first sheet pattern NS1 may include one of silicon or germanium, which is an elemental semiconductor material, a Group IV-IV compound semiconductor or a Group III-V compound semiconductor. Each of the first sheet patterns NS1 may include the same material as that of the first lower pattern BP1, or may include a material different from that of the first lower pattern BP1.

In the semiconductor device according to some embodiments, the first lower pattern BP1 may be a silicon lower pattern that includes silicon, and the first sheet pattern NS1 may be a silicon sheet pattern that includes silicon.

A width of the first sheet pattern NS1 in the second direction D2 may be increased or reduced in proportion to that of the first lower pattern BP1 in the second direction D2. In one embodiment, the widths of the first sheet patterns NS1 in the second direction D2, which are stacked in the third direction D3, are shown as being the same as each other, but the present disclosure is not limited thereto. In one embodiment, as the first sheet pattern NS1 becomes far away from the first lower pattern BP1, the widths of the first sheet patterns NS1 in the second direction D2, which are stacked in the third direction D3, may be reduced.

The field insulating layer 105 (e.g., shown in FIG. 2) may be disposed on the substrate 100. The field insulating layer 105 may be disposed on sidewalls of the first lower pattern BP1. The field insulating layer 105 is not disposed on the upper surface BP1_US of the first lower pattern.

In one embodiment, the field insulating layer 105 may entirely cover the sidewalls of the first lower pattern BP1. In one embodiment, the field insulating layer 105 may cover a portion of the sidewalls of the first lower pattern BP1. In this case, a portion of the first lower pattern BP1 may be more protruded in the third direction D3 than the upper surface of the field insulating layer 105.

Each of the first sheet patterns NS1 is disposed to be higher than the upper surface of the field insulating layer 105. The field insulating layer 105 may include, in one embodiment, an oxide layer, a nitride layer, an oxynitride layer or their combination layer. The field insulating layer 105 is shown as a single layer, but is not limited thereto.

A plurality of first gate structures GS1 (e.g., shown in FIG. 2) may be disposed on the substrate 100. Each of the first gate structures GSI may be extended in the second direction D2. The first gate structures GS1 may be disposed to be spaced apart from each other in the first direction D1. The first gate structures GS1 may be adjacent to each other in the first direction D1. In one embodiment, the first gate structures GS1 may be disposed on both sides of the first source/drain pattern 150 in the first direction D1.

The first gate structure GS1 may be disposed on the first active pattern AP1. The first gate structure GS1 and the first active pattern AP1 may be intersected or crossed each other.

The first gate structure GS1 and the first lower pattern BP1 may be intersected or crossed each other. The first gate structure GS1 may surround each of the first sheet patterns NS1.

As shown in FIG. 2, the first gate structure GS1 may include, in one embodiment, a first gate electrode 120, a first gate insulating layer 130, a first gate spacer 140, and a first gate capping pattern 145.

The first gate structure GS1 may include a plurality of inner gate structures INT_GS1, INT_GS2 and INT_GS3 (e.g., shown in FIG. 2) disposed between the first sheet patterns NS1 adjacent to each other in the third direction D3 and between the first lower pattern BP1 and the first sheet pattern NS1. The inner gate structures INT_GS1, INT_GS2 and INT_GS3 may be disposed between the upper surface BP1_US of the first lower pattern and the bottom surface NS1_BS of the first sheet pattern, and between the upper surface NS1_US of the first sheet pattern and the bottom surface NS1_BS of the first sheet pattern NS1, which face each other in the third direction D3.

The number of the inner gate structures INT_GS1, INT_GS2 and INT_GS3 (shown in FIG. 2) may be proportional to the number of the sheet patterns NS1 included in the active pattern AP1. In one embodiment, the number of the inner gate structures INT_GS1, INT_GS2 and INT_GS3 may be the same as the number of the first sheet patterns NS1. Since the first active pattern AP1 includes the plurality of first sheet patterns NS1, the first gate structure GS1 may include a plurality of inner gate structures.

The inner gate structures INT_GS1, INT_GS2 and INT_GS3 are in contact with the upper surface BP1_US of the first lower pattern, the upper surface NSI_US of the first sheet pattern and the bottom surface NS1_BS of the first sheet pattern.

The inner gate structures INT_GS1, INT_GS2 and INT_GS3 may be in contact with the first source/drain pattern 150, which will be described later. In one embodiment, the inner gate structures INT_GS1, INT_GS2 and INT_GS3 may be directly in contact with the first source/drain pattern 150.

The following description will be based on that the number of the inner gate structures INT_GS1, INT_GS2 and INT_GS3 is three.

The first gate structure GS1 may include a first inner gate structure INT_GS1, a second inner gate structure INT_GS2 and a third inner gate structure INT_GS3. The first inner gate structure INT_GS1, the second inner gate structure INT_GS2 and the third inner gate structure INT_GS3 may be sequentially disposed on the first lower pattern BP1.

The third inner gate structure INT_GS3 may be disposed between the first lower pattern BP1 and the first sheet pattern NS1. The third inner gate structure INT_GS3 may be disposed at a lowermost portion of the inner gate structures INT_GS1, INT_GS2 and INT_GS3. The third inner gate structure INT_GS3 may be in contact with the upper surface BP1_US of the first lower pattern.

The first inner gate structure INT_GS1 and the second inner gate structure INT_GS2 may be disposed between the first sheet patterns NS1 adjacent to each other in the third direction D3. The first inner gate structure INT_GS1 may be disposed at an uppermost portion of the inner gate structures INT_GS1, INT_GS2 and INT_GS3. The first inner gate structure INT_GS1 may be in contact with the bottom surface NS1_BS of the first sheet pattern disposed on the uppermost portion. The second inner gate structure INT_GS2 is disposed between the first inner gate structure INT_GS1 and the third inner gate structure INT_GS3.

The inner gate structures INT_GS1, INT_GS2 and INT_GS3 include a first gate electrode 120 and a first gate insulating layer 130, which are disposed between the first sheet patterns NS1 adjacent to each other and between the first lower pattern BP1 and the first sheet pattern NS1.

In one embodiment, a width of the first inner gate structure INT_GS1 in the first direction D1 may be the same as that of the second inner gate structure INT_GS2 in the first direction D1. A width of the third inner gate structure INT_GS3 in the first direction D1 may be the same as that of the second inner gate structure INT_GS2 in the first direction D1.

In one embodiment, a width of the third inner gate structure INT_GS3 in the first direction D1 may be greater than that of the second inner gate structure INT_GS2 in the first direction D1. The width of the first inner gate structure INT_GS1 in the first direction D1 may be the same as that of the second inner gate structure INT_GS2 in the first direction D1.

In one embodiment, the width of the second inner gate structure INT_GS2 may be measured in the middle between the upper surface NS1_US of the first sheet pattern and the bottom surface NS1_BS of the first sheet pattern, which face each other in the third direction D3.

FIG. 5 illustrates a plan view at a level of the second inner gate structure INT_GS2. When a portion in which a first source/drain contact 180 is formed is excluded, a plan view at a level of the other inner gate structures INT_GS1 and INT_GS3 may be similar to that of FIG. 5.

The first gate electrode 120 may be disposed on the first lower pattern BP1. The first gate electrode 120 and the first lower pattern BP1 may be intersected or crossed each other. The first gate electrode 120 may surround the first sheet pattern NS1.

The first gate electrode 120 may be disposed on the first lower pattern BP1. The first gate electrode 120 and the first lower pattern BP1 may be intersected or crossed each other. The first gate electrode 120 may surround the first sheet pattern NS1. A portion of the first gate electrode 120 may be disposed between the first sheet patterns NS1 adjacent to each other and between the first lower pattern BP1 and the first sheet pattern NS1.

The first gate electrode 120 may include at least one of a metal, a metal alloy, a conductive metal nitride, a metal silicide, a doped semiconductor material, a conductive metal oxide, or a conductive metal oxynitride. For example, the first gate electrode 120 may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or their combinations, but is not limited thereto. The conductive metal oxide and the conductive metal oxynitride may include an oxidized form of the above-described materials, but are not limited thereto.

The first gate electrode 120 may be disposed on both sides of the first source/drain pattern 150, which will be described later. The first gate structure GS1 may be disposed on both sides of the first source/drain pattern 150 in the first direction D1.

In one embodiment, the first gate electrodes 120 disposed at both sides of the first source/drain pattern 150 may be normal gate electrodes used as gates of a transistor. In one embodiment, the first gate electrode 120 disposed on one side of the first source/drain pattern 150 is used as a gate of the transistor, but the first gate electrode 120 disposed on the other side of the first source/drain pattern 150 may be a dummy gate electrode.

The first gate insulating layer 130 may be extended along the upper surface of the field insulating layer 105 and the upper surface BP1_US of the first lower pattern. The first gate insulating layer 130 may surround the plurality of first sheet patterns NS1. The first gate insulating layer 130 may be disposed along the periphery of the first sheet pattern NS1. The first gate electrode 120 is disposed on the first gate insulating layer 130. The first gate insulating layer 130 is disposed between the first gate electrode 120 and the first sheet pattern NS1. A portion of the first gate insulating layer 130 may be disposed between the first sheet patterns NS1 adjacent to each other in the third direction D3 and between the first lower pattern BP1 and the first sheet pattern NS1.

The first gate insulating layer 130 may include a first gate interface insulating layer 131 and a first gate high dielectric constant insulating layer 132. The first gate high dielectric constant insulating layer 132 may be disposed between the first gate interface insulating layer 131 and the first gate electrode 120.

The first gate interface insulating layer 131 may be extended along the upper surface BP1_US of the first lower pattern. The first gate interface insulating layer 131 may be extended along the first source/drain pattern 150. The first gate interface insulating layer 131 may be disposed along the periphery of the first sheet pattern NS1. The first gate interface insulating layer 131 may be directly in contact with the first lower pattern BP, the first source/drain pattern 150 and the first sheet pattern NS1.

The first gate interface insulating layer 131 may not be extended along the upper surface of the field insulating layer 105. The first gate interface insulating layer 131 may not be extended along sidewalls of the first gate spacer 140, which will be described later. However, according to a method of forming the first gate interface insulating layer 131, the first gate interface insulating layer 131 may be extended along the upper surface of the field insulating layer 105 and the sidewalls of the first gate spacer 140.

The first gate high dielectric constant insulating layer 132 may be extended along the upper surface of the field insulating layer 105 and the upper surface BP1_US of the first lower pattern. The first gate high dielectric constant insulating layer 132 may be extended along the first source/drain pattern 150. The first gate high dielectric constant insulating layer 132 may be disposed along the periphery of the first sheet pattern NS1. The first gate high dielectric constant insulating layer 132 may be extended along the sidewalls of the first gate spacer 140, which will be described later.

The first gate interface insulating layer 131 may include at least one of silicon oxide, silicon-germanium oxide or germanium oxide. The first gate high dielectric constant insulating layer 132 may include at least one of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

According to some embodiments, the semiconductor device may include a negative capacitance (NC) FET based on a negative capacitor. In one embodiment, the first gate high dielectric constant insulating layer 132 may include a ferroelectric material layer having ferroelectric characteristics. In one embodiment, the first gate high dielectric constant insulating layer 132 may include a ferroelectric material layer having ferroelectric characteristics and a paraelectric material layer having paraelectric characteristics.

The ferroelectric material layer may have a negative capacitance, and the paraelectric material layer may have a positive capacitance. In one embodiment, when two or more capacitors are connected in series, and the capacitance of each capacitor has a positive value, the total capacitance is more reduced than the capacitance of each individual capacitor. In one embodiment, when at least one of capacitances of two or more capacitors connected in series has a negative value, the total capacitance may have a positive value and may be greater than an absolute value of each individual capacitance.

When a ferroelectric material layer having a negative capacitance and a paraelectric material layer having a positive capacitance are connected in series, the total capacitance value of the ferroelectric material layer and the paraelectric material layer, which are connected in series, may be increased. Based on the total capacitance value that is increased, a transistor having a ferroelectric material layer may have a subthreshold swing (SS) less than 60 mV/decade at a room temperature.

The ferroelectric material layer may have ferroelectric characteristics. For example, the ferroelectric material layer may include at least one of hafnium oxide, hafnium zirconium oxide, barium strontium titanium oxide, barium titanium oxide, or lead zirconium titanium oxide. In this case, for example, the hafnium zirconium oxide may be a material doped with zirconium (Zr) in hafnium oxide. For another example, the hafnium zirconium oxide may be a compound of hafnium (Hf) and zirconium (Zr) and oxygen (O).

The ferroelectric material layer may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), or tin (Sn). A type of the dopant included in the ferroelectric material layer may be varied depending on the ferroelectric material of the ferroelectric material layer.

When the ferroelectric material layer includes hafnium oxide, the dopant included in the ferroelectric material layer may include at least one of gadolinium (Gd), silicon (Si), zirconium (Zr), aluminum (Al), or yttrium (Y).

When the dopant is aluminum (Al), the ferroelectric material layer may include aluminum of 3 at % to 8 at % (atomic %). In this case, a ratio of the dopant may be a ratio of aluminum to a sum of hafnium and aluminum.

When the dopant is silicon (Si), the ferroelectric material layer may include silicon of 2 at % to 10 at %. When the dopant is yttrium (Y), the ferroelectric material layer may include yttrium of 2 at % to 10 at %. When the dopant is gadolinium (Gd), the ferroelectric material layer may include gadolinium of 1 at % to 7 at %. When the dopant is zirconium (Zr), the ferroelectric material layer may include zirconium of 50 at % to 80 at %.

The paraelectric material layer may have paraelectric characteristics. For example, the paraelectric material layer may include at least one of silicon oxide or metal oxide having a high dielectric constant. The metal oxide included in the paraelectric material layer may include, but is not limited to, at least one of hafnium oxide, zirconium oxide, or aluminum oxide.

The ferroelectric material layer and the paraelectric material layer may include the same material. Although the ferroelectric material layer has ferroelectric characteristics, the paraelectric material layer may not have ferroelectric characteristics. For example, when the ferroelectric material layer and the paraelectric material layer include hafnium oxide, a crystal structure of hafnium oxide included in the ferroelectric material layer is different from that of hafnium oxide included in the paraelectric material layer.

The ferroelectric material layer may have a thickness having ferroelectric characteristics. The thickness of the ferroelectric material layer may be, for example, 0.5 nm to 10 nm, but is not limited thereto. Since a threshold thickness indicating ferroelectric characteristics may be varied depending on each ferroelectric material, the thickness of the ferroelectric material layer may be varied depending on the ferroelectric material.

In one embodiment, the first gate high dielectric constant insulating layer 132 may include one ferroelectric material layer. In one embodiment, the first gate high dielectric constant insulating layer 132 may include a plurality of ferroelectric material layers spaced apart from each other. The first gate high dielectric constant insulating layer 132 may have a stacked layer structure in which a plurality of ferroelectric material layers and a plurality of paraelectric material layers are alternately stacked.

The first gate spacer 140 may be disposed on sidewalls of the first gate electrode 120. The first gate spacer 140 may not be disposed between the first lower pattern BP1 and the first sheet pattern NS1 and between the first sheet patterns NS1 adjacent to each other in the third direction D3.

The first gate spacer 140 may include an inner sidewall 140_ISW, a connection sidewall 140_CSW and an outer sidewall 140_OSW. The inner sidewall 140_ISW of the first gate spacer faces the sidewall of the first gate electrode 120, which are extended in the second direction D2. The inner sidewall 140_ISW of the first gate spacer 140 may be extended in the second direction D2. The inner sidewall 140_ISW of the first gate spacer 140 may be a surface opposite to the outer sidewall 140_OSW of the first gate spacer facing a first interlayer insulating layer 190. The connection sidewall 140_CSW of the first gate spacer connects the inner sidewall 140_ISW2 of the first gate spacer with the outer sidewall 140_OSW of the first gate spacer. The connection sidewall 140_CSW of the first gate spacer may be extended in the first direction D1.

The first gate insulating layer 130 may be extended along the inner sidewall 140_ISW of the first gate spacer. The first gate insulating layer 130 may be in contact with the inner sidewall 140_ISW of the first gate spacer.

For example, the first gate spacer 140 may include at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), or their combinations. In one embodiment, the first gate spacer 140 is shown as a single layer, but is not limited thereto.

The first gate capping pattern 145 may be disposed on the first gate electrode 120 and the first gate spacer 140. An upper surface of the first gate capping pattern 145 may be disposed on the same plane as that of the first interlayer insulating layer 190. In one embodiment, the upper surface of the first gate capping pattern 145 may be an upper surface of the first gate structure GS1. In one embodiment, the first gate capping pattern 145 may be disposed between the first gate spacers 140.

For example, the first gate capping pattern 145 may include at least one of silicon nitride (SiN), silicon oxynitride (SiON), silicon carbonitride (SiCN), silicon oxycarbonitride (SiOCN), or their combinations. The first gate capping pattern 145 may include a material having an etch selectivity with respect to the first interlayer insulating layer 190.

In one embodiment, the first gate structure GS1 may not include the first gate capping pattern 145. In this case, the upper surface of the first gate capping pattern GS1 may include an upper surface of the first gate electrode 120 and an upper surface of the first gate spacer 140.

The first source/drain pattern 150 may be disposed on the first active pattern AP1. The first source/drain pattern 150 may be disposed on the first lower pattern BP1. The first source/drain pattern 150 is connected to the first sheet pattern NS1. The first source/drain pattern 150 is in contact with the first sheet pattern NS1.

The first source/drain pattern 150 may be disposed on a side of the first gate structure GS1. The first source/drain pattern 150 may be disposed between the first gate structures GS1 adjacent to each other in the first direction D1. In one embodiment, the first source/drain pattern 150 may be disposed on both sides of the first gate structure GS1. In one embodiment, the first source/drain pattern 150 may be disposed on one side of the first gate structure GS1, and may not be disposed on the other side of the first gate structure GS1.

The first source/drain pattern 150 may be included in a source/drain of a transistor that uses the first sheet pattern NS1 as a channel region.

The first source/drain pattern 150 may be disposed in a first source/drain recess 150R. The first source/drain pattern 150 may fill the first source/drain recess 150R.

The first source/drain recess 150R may be extended in the third direction D3. The first source/drain recess 150R may be defined between the first gate structures GS1 adjacent to each other in the first direction D1.

A bottom surface of the first source/drain recess 150R may be defined by the first lower pattern BP1. A sidewall of the first source/drain recess 150R may be defined by the first sheet pattern NS1 and the inner gate structures INT_GS, INT_GS2 and INT_GS3. The inner gate structures INT_GS1, INT_GS2 and INT_GS3 may define a portion of the sidewall of the first source/drain recess 150R. In FIG. 5, the connection sidewall 140_CSW of the first gate spacer is included in the first source/drain recess 150R (shown in FIG. 2).

The inner gate structures INT_GS1, INT_GS2 and INT_GS3 may include an upper surface facing the bottom surface NS1_BS of the first sheet pattern. The inner gate structures INT_GS1, INT_GS2 and INT_GS3 include a bottom surface facing the upper surface NS1_US of the first sheet pattern or the upper surface BP1_US of the first lower pattern. Each of the inner gate structures INT_GS1, INT_GS2 and INT_GS3 include a sidewall connecting the upper surface with the bottom surface thereof. The sidewall of each of the inner gate structures INT_GS1, INT_GS2 and INT_GS3 may define a portion of the sidewall of the first source/drain recess 150R.

A boundary between the first gate insulating layer 130 and the first lower pattern BP1 may be the upper surface BP1_US of the first lower pattern between the first sheet pattern NS1 disposed at the lowermost portion and the first lower pattern BP1. The upper surface BP1_US of the first lower pattern may be a boundary between the third inner gate structure INT_GS3 and the first lower pattern BP1. The bottom surface of the first source/drain recess 150R is lower than the upper surface BP1_US of the first lower pattern.

The sidewall of the first source/drain recess 150R may have a wavy shape. The first source/drain recess 150R may include a plurality of width extension regions 150R_ER. The width extension region 150R_ER of each of the first source/drain recesses may be defined above the upper surface BP1_US of the first lower pattern.

The width extension region 150R_ER of the first source/drain recess may be defined between first sheet patterns NS1 adjacent to each other in the third direction D3. The width extension region 150R_ER of the first source/drain recess may be defined between the first lower pattern BP1 and the first sheet pattern NS1. The width extension region 150R_ER of the first source/drain recess may be extended between the first sheet patterns NS1 adjacent to each other in the third direction D3. The width extension region 150R_ER of the first source/drain recess may be defined among the inner gate structures INT_GS1, INT_GS2 and INT_GS3 adjacent to one another in the first direction D1.

As the width extension region 150R_ER of each of the first source/drain recesses becomes far away from the upper surface BP1_US of the first lower pattern, the width extension region 150R_ER may include a portion in which a width in the first direction D1 is increased and a portion in which a width in the first direction D1 is reduced. In one embodiment, as the width extension region 150R_ER of the first source/drain recess becomes far away from the upper surface BP1_US of the first lower pattern, the width of the width extension region 150R_ER of the first source/drain recess may be increased and then reduced.

In the width extension region 150R_ER of each of the first source/drain recesses, a point at which the width of the width extension region 150R_ER of the first source/drain recess is maximum is positioned between the first sheet pattern NS1 and the first lower pattern BP1 or between the first sheet patterns NS1 adjacent to each other in the third direction D3.

The first source/drain pattern 150 may be in contact with the first sheet pattern NS1 and the first lower pattern BP1. Since the first gate spacer 140 is not disposed between the first sheet patterns NS1 adjacent to each other and between the first lower pattern BP1 and the first sheet pattern NS1, the inner gate structures INT_GS1, INT_GS2 and INT_GS3 may be in contact with the first source/drain patterns 150. A portion of the first source/drain pattern 150 may be in contact with the connection sidewall 140_CSW of the first gate spacer. The first gate insulating layer 130 of the inner gate structures INT_GS1, INT_GS2 and INT_GS3 may be in contact with the first source/drain pattern 150.

The first source/drain pattern 150 may include an epitaxial pattern. The first source/drain pattern 150 includes a semiconductor material. The first source/drain pattern 150 may include a plurality of insertion epitaxial regions 151, a first epitaxial region 152 and a second epitaxial region 153.

The plurality of insertion epitaxial regions 151 may be disposed between the first lower pattern BP1 and the first sheet pattern NS1 and between first sheet patterns NS1 adjacent to each other in the third direction D3. The respective insertion epitaxial regions 151 may be spaced apart from each other.

Each of the insertion epitaxial regions 151 may include an outer side 151OSW and an inner side 151ISW, which are opposite to each other in the first direction D1. Each of the insertion epitaxial regions 151 may be in contact with the first gate insulating layer 130 of the inner gate structures INT_GS1, INT_GS2 and INT_GS3. The first gate insulating layer 130 of the inner gate structures INT_GS1, INT_GS2 and INT_GS3 may be in contact with the outer side 151OSW of the insertion epitaxial region.

In FIG. 5, the insertion epitaxial region 151 may be in contact with the connection sidewall 140_CSW of the first gate spacer. The insertion epitaxial region 151 may be disposed between the connection sidewalls 140_CSW of the first gate spacer, which face each other in the second direction D2. The insertion epitaxial region 151 may be continuously formed between the connection sidewalls 140_CSW of the first gate spacer, which face each other in the second direction D2.

In FIG. 6, the plurality of insertion epitaxial regions 151 may include a first insertion epitaxial region 151_1 and a second insertion epitaxial region 151_2, which are closest to each other in the third direction D3. The first insertion epitaxial region 151_1 and the second insertion epitaxial region 151_2 are spaced apart from each other in the third direction D3. The first insertion epitaxial region 151_1 is not in contact with the second insertion epitaxial region 151_2. The first insertion epitaxial region 151_1 and the second insertion epitaxial region 151_2 are separated from each other by the first sheet pattern NS1 disposed between the first insertion epitaxial region 151_1 and the second insertion epitaxial region 151_2.

The plurality of first sheet patterns NS1 may include a first lower sheet pattern NS1_2 and a first upper sheet pattern NS1_1. The upper surface NS1_US of the first lower sheet pattern NS1_2 faces the bottom surface NS1_BS of the first upper sheet pattern NS1_1. Each of the insertion epitaxial regions 151 may be continuously formed from the upper surface NS1_US of the first lower sheet pattern NS1_2 to the bottom surface NS1_BS of the first upper sheet pattern NS1_BS. In other words, the insertion epitaxial region 151 is continuously extended without being cut between the upper surface NS1_US of the first lower sheet pattern NS1_2 and the bottom surface NS1_BS of the first upper sheet pattern NS1_1.

The insertion epitaxial region 151 may have a first thickness W11 at a point adjacent to the upper surface NS1_US of the first sheet pattern or the bottom surface NS1_BS of the first sheet pattern. The insertion epitaxial region 151 may have a second thickness W12 at an intermediate point between the upper surface NS1_US of the first sheet pattern and the bottom surface NS1_BS of the first sheet pattern. In one embodiment, the first thickness W11 may be the same as the second thickness W12.

In FIGS. 2, 5 and 6, each of the outer side 151OSW of the insertion epitaxial region and the inner side 151ISW of the insertion epitaxial region may include a curved surface. In one embodiment, the outer side 151OSW of the insertion epitaxial region may have a convex shape. The inner side 151ISW of the insertion epitaxial region may have a concave shape.

The first epitaxial region 152 may be continuously formed along the first source/drain recess 150R. The first epitaxial region 152 may be extended along the sidewall of the first source/drain recess 150R and the bottom surface of the first source/drain recess 150R.

The first epitaxial region 152 may be in contact with each insertion epitaxial region 151. The first epitaxial region 152 may be in contact with the inner side 151ISW of the insertion epitaxial region.

The first epitaxial region 152 is in contact with each of the first sheet patterns NS1. Since the insertion epitaxial region 151 is disposed between the first epitaxial region 152 and the inner gate structures INT_GS1, INT_GS2 and INT_G3, the first epitaxial region 152 may not be in contact with the first gate insulating layer 130 of the inner gate structures INT_GS1, INT_GS2 and INT_GS3.

In FIG. 5, the first epitaxial region 152 is shown as covering a portion of the outer sidewall 140_OSW of the first gate spacer, but is not limited thereto.

The second epitaxial region 153 may be disposed on the first epitaxial region 152. The second epitaxial region 153 may fill the first source/drain recess 150R. The first epitaxial region 152 may be disposed between the second epitaxial region 153 and the insertion epitaxial region 151.

For example, the insertion epitaxial region 151 may include silicon-germanium. The insertion epitaxial region 151 may include a silicon-germanium film. The insertion epitaxial region 151 may include impurities. For example, the impurities doped in the insertion epitaxial region 151 may include at least one of arsenic (As), boron (B) or carbon (C).

Each of the first epitaxial region 152 and the second epitaxial region 153 may include silicon. Each of the first epitaxial region 152 and the second epitaxial region 153 may include a silicon film. Each of the first epitaxial region 152 and the second epitaxial region 153 may include n-type doped impurities. For example, the n-type impurities may include at least one of phosphorus (P), arsenic (As), antimony (Sb), or bismuth (Bi).

For example, the n-type impurities doped in the first epitaxial region 152 may include at least one of arsenic (As), antimony (Sb), or bismuth (Bi). The n-type impurities doped in the second epitaxial region 153 may include phosphorus (P). In other words, the second epitaxial region 153 may be silicon doped with phosphorus (P).

In one embodiment, a boundary between the first epitaxial region 152 and the second epitaxial region 153, which include the silicon film, may not be distinguished from each other. Since kinds of the n-type impurities doped in the first epitaxial region 152 and the second epitaxial region 153 may be different from each other, the boundary between the first epitaxial region 152 and the second epitaxial region 153 may be distinguished through component analysis of the n-type doped impurities.

A germanium fraction of the first epitaxial region 152 is different from that of the insertion epitaxial region 151. In one embodiment, the germanium fraction of the first epitaxial region 152 is smaller than that of the insertion epitaxial region 151. A germanium fraction of the second epitaxial region 153 is smaller than that of the insertion epitaxial region 151.

Since each of the first epitaxial region 152 and the second epitaxial region 153 may be a silicon film doped with n-type impurities, the germanium fraction of the first epitaxial region 152 and the germanium fraction of the second epitaxial region 153 may be 0 (zero). When the germanium fraction of the silicon-germanium film is 0 (zero), the silicon-germanium film is a silicon film. Therefore, in the description of the present disclosure, the silicon film will be described as a silicon-germanium film in which the germanium fraction is 0 (zero).

The source/drain etch stop layer 185 may be extended along a profile of the first source/drain pattern 150 and the outer sidewall 140_OSW of the first gate spacer. The source/drain etch stop layer 185 may be disposed on the upper surface of the field insulating layer 105.

The source/drain etch stop layer 185 may not be extended along the sidewall of the first gate capping pattern 145. In one embodiment, the source/drain etch stop layer 185 may be extended along the sidewall of the first gate capping pattern 145.

The source/drain etch stop layer 185 may include a material having an etch selectivity with respect to the first interlayer insulating layer 190, which will be described later. The source/drain etch stop layer 185 may include at least one of silicon nitride (SiN), silicon oxynitride (SiON), silicon oxycarbonitride (SiOCN), silicon boron nitride (SiBN), silicon oxy boron nitride (SiOBN), silicon oxycarbide (SiOC), or their combinations.

The first interlayer insulating layer 190 may be disposed on the source/drain etch stop layer 185. The first interlayer insulating layer 190 may be disposed on the first source/drain pattern 150. The first interlayer insulating layer 190 may not cover the upper surface of the first gate capping pattern 145. In one embodiment, the upper surface of the first interlayer insulating layer 190 may be disposed on the same plane as that of the first gate capping pattern 145.

For example, the first interlayer insulating layer 190 may include at least one of silicon oxide, silicon nitride, silicon oxynitride, or a low dielectric constant material. The low dielectric constant material may include Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethylCycloTetraSiloxane (OMCTS), HexaMethylDiSiloxane (HMDS), TriMethylSilyl Borate (TMSB), DiAcetoxy Ditertiary Butoxy Siloxane (DADBS), TriMethylSilil Phosphate (TMSP), Poly TetraFluoroEthylene (PTFE), Tonen SilaZen (TOSZ), Fluoride Silicate Glass (FSG), polyimide nanofoams such as polypropylene oxide, Carbon Doped silicon Oxide (CDO), Organo Silicate Glass (OSG), SILK, Amorphous Fluorinated Carbon, silica aerogels, silica xerogels, mesoporous silica, or their combinations, but is not limited thereto.

The first source/drain contact 180 may be disposed on the first source/drain pattern 150. The first source/drain contact 180 may be connected to the first source/drain pattern 150. The first source/drain contact 180 may be connected to the first source/drain pattern 150 by passing through the first interlayer insulating layer 190 and the source/drain etch stop layer 185.

A first metal silicide layer 155 may be disposed between the first source/drain contact 180 and the first source/drain pattern 150.

The first source/drain contact 180 is shown as a single layer, but this is for convenience of description, and the present disclosure is not limited thereto. For example, the first source/drain contact 180 may include at least one of a metal, a metal alloy, a conductive metal nitride, a conductive metal carbide, a conductive metal oxide, a conductive metal carbonitride, or a two-dimensional (2D) material. The first metal silicide layer 155 may include a metal silicide.

A second interlayer insulating layer 191 is disposed on the first interlayer insulating layer 190. For example, the second interlayer insulating layer 191 may include at least one of silicon oxide, silicon nitride, silicon oxynitride, or a low dielectric constant material.

An etch stop layer having an etch selectivity with respect to the second interlayer insulating layer 191 may be further disposed between the first interlayer insulating layer 190 and the second interlayer insulating layer 191.

The wiring structure 205 may be disposed in the second interlayer insulating layer 191. The wiring structure 205 may be connected to the first source/drain contact 180. The wiring structure 205 may include a wiring line 207 and a wiring via 206.

The wiring line 207 and the wiring via 206 are shown as being distinguished from each other, but this is only for convenience of description, and the present disclosure is not limited thereto. That is, in one embodiment, after the wiring via 206 is formed, the wiring line 207 may be formed. In one embodiment, the wiring via 206 and the wiring line 207 may be formed simultaneously.

Each of the wiring line 207 and the wiring via 206 is shown as a single film, but the present disclosure is not limited thereto. For example, each of the wiring line 207 and the wiring via 206 may include at least one of a metal, a metal alloy, a conductive metal nitride, a conductive metal carbide, a conductive metal oxide, a conductive metal carbonitride, or a two-dimensional (2D) material.

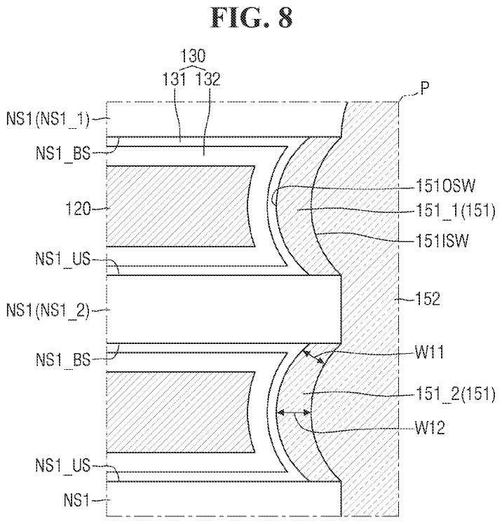

FIGS. 8 to 11 illustrate a semiconductor memory device according to some

embodiments. The following description will be based on differences from the description made with reference to FIGS. 1 to 7. FIGS. 8 to 11 are enlarged views illustrating a portion P of FIG. 2.

In FIG. 8, in the semiconductor device, according to some embodiments, a first thickness W11 of the insertion epitaxial region 151 at a point adjacent to the upper surface NS1_US of the first sheet pattern or the bottom surface NS1_BS of the first sheet pattern may be different from a second thickness W12 of the insertion epitaxial region 151 at an intermediate point between the upper surface NS1_US of the first sheet pattern and the bottom surface NS1_BS of the first sheet pattern.

In one embodiment, the first thickness W11 of the insertion epitaxial region 151 may be greater than the second thickness W12 of the insertion epitaxial region 151.

In one embodiment, the first thickness W11 of the insertion epitaxial region 151 may be smaller than the second thickness W12 of the insertion epitaxial region 151.

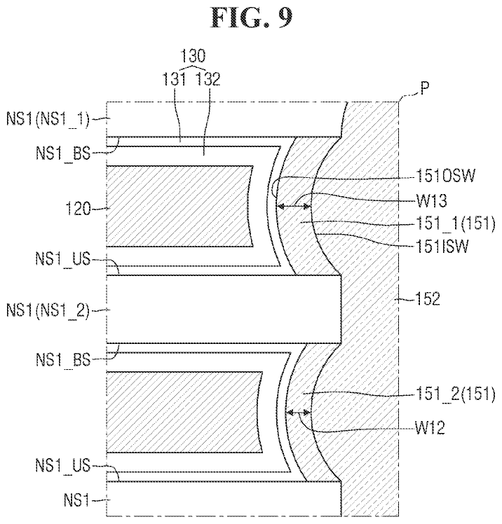

Referring to FIG. 9, in the semiconductor device according to some embodiments, a thickness W13 of the first insertion epitaxial region 151_1 may be different from the thickness W12 of the second insertion epitaxial region 151_2.

For example, the thickness W13 of the first insertion epitaxial region 151_1 at the intermediate point of the upper surface NS1_US of the first sheet pattern and the bottom surface NS1_BS of the first sheet pattern may be greater than the thickness W12 of the second insertion epitaxial region 151_2 at the intermediate point of the upper surface NS1_US of the first sheet pattern and the bottom surface NS1_BS of the first sheet pattern.

In one embodiment, the thickness W13 of the first insertion epitaxial region 151_1 at the intermediate point of the upper surface NS1_US of the first sheet pattern and the bottom surface NS1_BS of the first sheet pattern may be smaller than the thickness W12 of the second insertion epitaxial region 151_2 at the intermediate point of the upper surface NS1_US of the first sheet pattern and the bottom surface NS1_BS of the first sheet pattern.

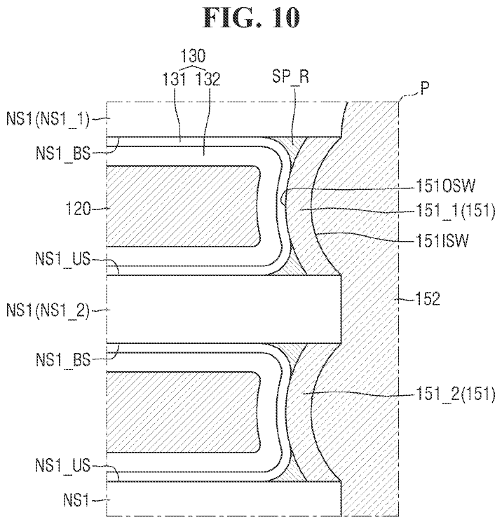

Referring to FIGS. 2 and 10, in the semiconductor device according to some embodiments, a semiconductor residue pattern SP_R may be disposed between the inner gate structures INT_GS1, INT_GS2 and INT_GS3 and the insertion epitaxial region 151.

The semiconductor residue pattern SP_R may be in contact with the first sheet pattern NS1. The semiconductor residue pattern SP_R may be in contact with the outer side 151OSW of the insertion epitaxial region and the sidewalls of the inner gate structures INT_GS1, INT_GS2 and INT_GS3.

The semiconductor residue pattern SP_R may include, for example, silicon-germanium.

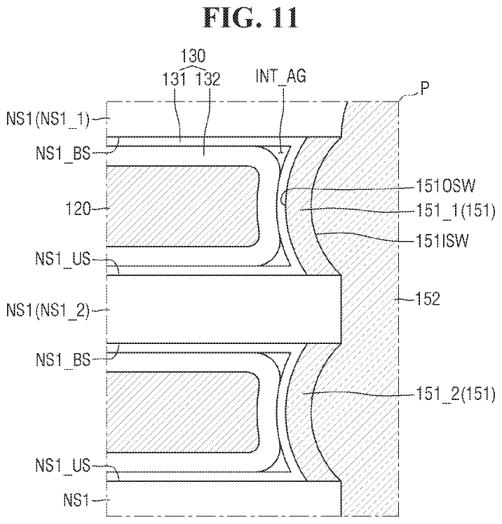

Referring to FIGS. 2 and 11, in the semiconductor device, according to some embodiments, an inner gate air gap INT_AG may be disposed between the inner gate structures INT_GS1, INT_GS2 and INT_GS3 and the insertion epitaxial region 151.

The inner gate air gap INT_AG may be disposed between the insertion epitaxial region 151 and the first gate insulating layer 130 of the inner gate structures INT_GS1, INT_GS2 and INT_GS3. The inner gate air gap INT_AG may be defined among the insertion epitaxial region 151, the first sheet pattern NS1 and the inner gate structures INT_GS1, INT_GS2 and INT_GS3.

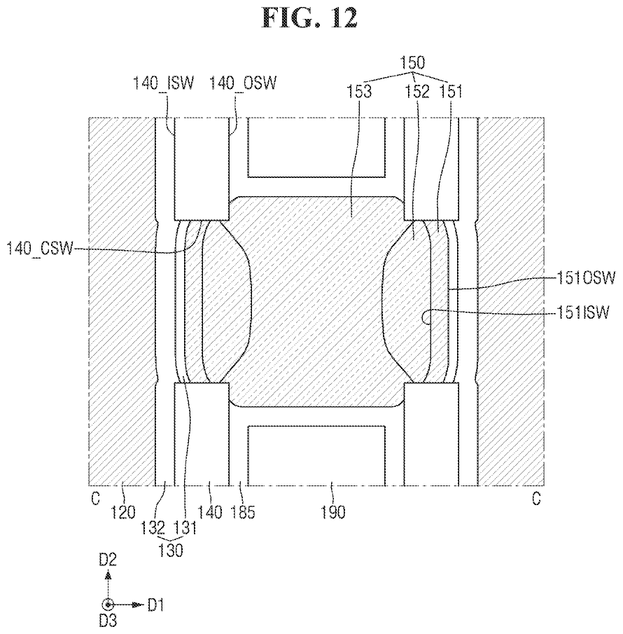

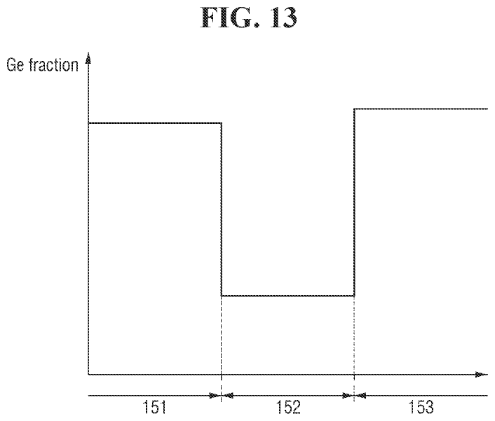

FIGS. 12 and 13 illustrate a semiconductor memory device according to some embodiments. The following description will be based on differences from the description made with reference to FIGS. 1 to 7. FIG. 12 is a plan view taken along line C-C of FIG. 2. FIG. 13 is a view illustrating a germanium fraction of a first source/drain pattern.

Referring to FIGS. 12 and 13, in the semiconductor device according to some embodiments, the first active pattern AP1 may be disposed in a region in which a PMOS is formed.

Each of the first epitaxial region 152 and the second epitaxial region 153 may include silicon-germanium. Each of the first epitaxial region 152 and the second epitaxial region 153 may include a silicon-germanium film.

Each of the first epitaxial region 152 and the second epitaxial region 153 may include p-type doped impurities. For example, the p-type impurities may include at least one of boron (B) or gallium (Ga).

A germanium fraction of the first epitaxial region 152 is smaller than that of the insertion epitaxial region 151. A germanium fraction of the second epitaxial region 153 is greater than that of the first epitaxial region 152. The germanium fraction of the second epitaxial region 153 is shown as being greater than that of the insertion epitaxial region 151, but is not limited thereto.

In FIG. 12, the first epitaxial region 152 may include an inner side facing the second epitaxial region 153 and an outer side that is in contact with the insertion epitaxial region 151. The inner side of the first epitaxial region 152 may include a facet portion extended from the inner sidewall 140_ISW of the first gate spacer. In one embodiment, the first epitaxial region 152 may not be in contact with the outer sidewall 140_OSW of the first gate spacer.

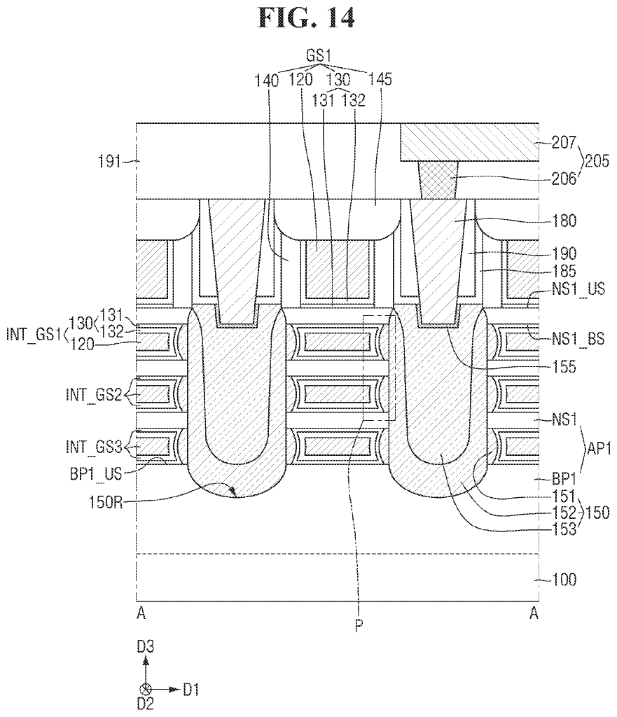

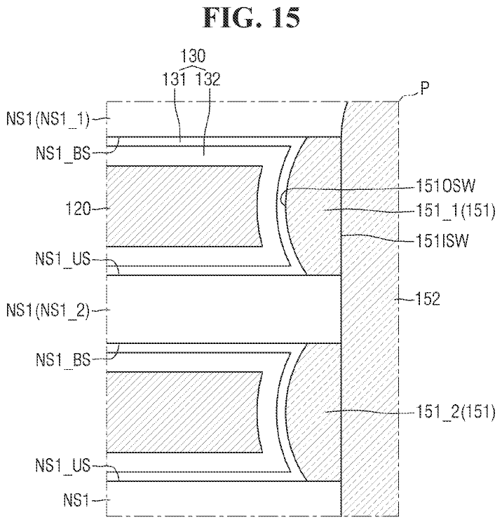

FIGS. 14 and 15 illustrate a semiconductor device according to some embodiments. The following description will be based on differences from the description made with reference to FIGS. 1 to 7. FIG. 15 is an enlarged view illustrating a portion P of FIG. 14.

Referring to FIGS. 14 and 15, in the semiconductor device, according to some embodiments, the first source/drain recess 150R does not include a plurality of width extension regions (150R_ER of FIG. 2).

The sidewall of the first source/drain recess 150R does not have a wavy shape. As an upper portion of the sidewall of the first source/drain recess 150R becomes far away from the first lower pattern BP1, its width in the first direction D1 may be reduced.

The outer side 151OSW of the insertion epitaxial region may include a curved surface. The inner side 151ISW of the insertion epitaxial region may be planar. In one embodiment, the outer side 151OSW of the insertion epitaxial region may have a convex shape.

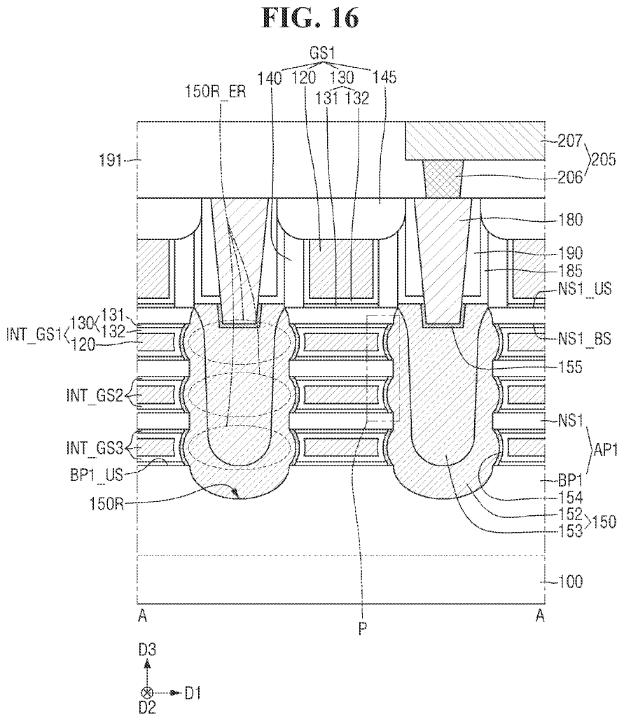

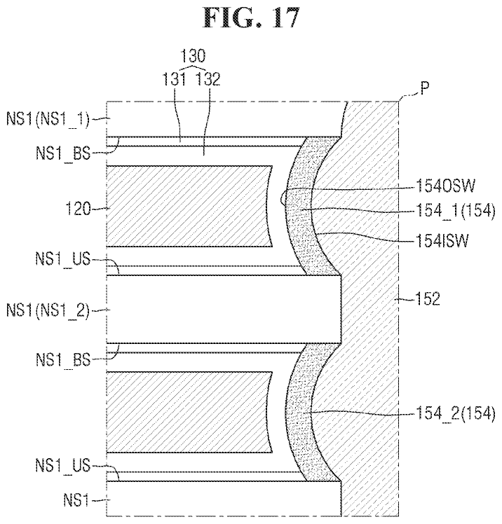

FIGS. 16 and 17 illustrate a semiconductor device according to some embodiments. The following description will be based on differences from the description made with reference to FIGS. 1 to 7. FIG. 17 is an enlarged view illustrating a portion P of FIG. 16.

Referring to FIGS. 16 and 17, the semiconductor device, according to some embodiments, may further include a plurality of insertion insulating patterns 154.

The first source/drain pattern 150 does not include a plurality of insertion epitaxial regions 151 (of FIG. 2).

The insertion insulating pattern 154 may include silicon nitride-germanium. The insertion insulating pattern 154 may be a silicon nitride-germanium film.

The plurality of insertion insulating patterns 154 may be disposed between the first lower pattern BP1 and the first sheet pattern NS1 and between the first sheet patterns NS1 adjacent to each other in the third direction D3. The respective insertion insulating patterns 154 may be spaced apart from each other.

Each of the insertion insulating patterns 154 may include an outer side 154OSW and an inner side 154ISW, which are opposite to each other in the first direction D1. The outer side 154OSW of each of the insertion insulating patterns may be in contact with the first gate insulating layer 130 of the inner gate structures INT_GS1, INT_GS2 and INT_GS3.

The plurality of insertion insulating patterns 154 may include a first insertion insulating pattern 154_1 and a second insertion insulating pattern 154_2, which are closest to each other in the third direction D3. The first insertion insulating pattern 154_1 and the second insertion insulating pattern 154_2 are spaced apart from each other in the third direction D3. The first insertion insulating pattern 154_1 is not in contact with the second insertion insulating pattern 154_2. The first insertion insulating pattern 154_1 and the second insertion insulating pattern 154_2 are separated from each other by the first sheet pattern NS1.

In one embodiment, the outer side 154OSW of the insertion insulating pattern may have a convex shape. The inner side 154ISW of the insertion insulating pattern may have a concave shape.

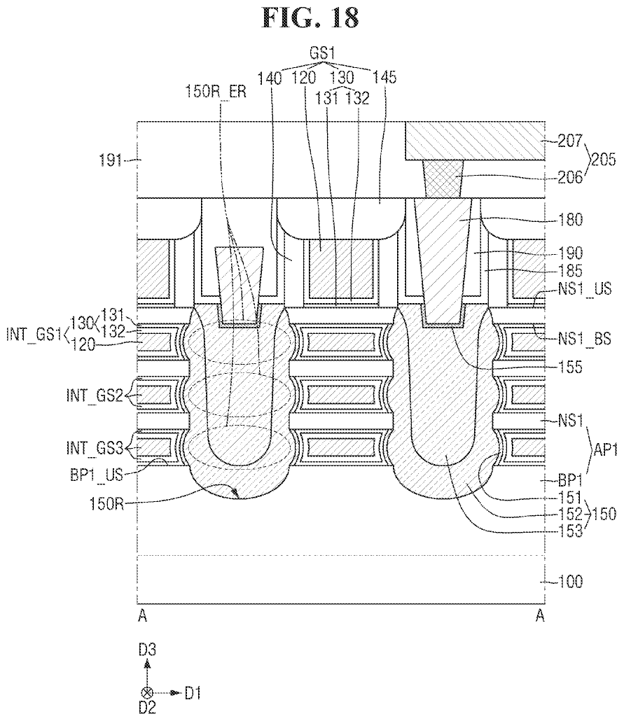

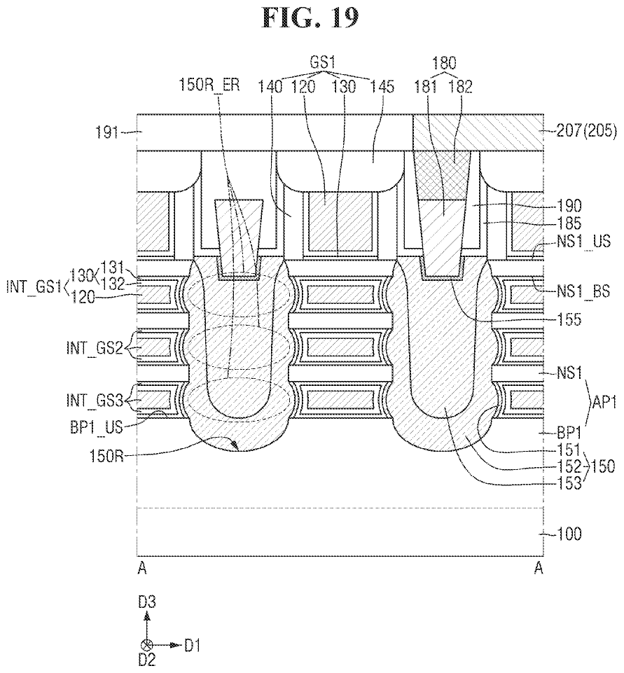

FIGS. 18 and 19 illustrate a semiconductor device according to some embodiments. The following description will be based on differences from the description made with reference to FIGS. 1 to 7.

Referring to FIG. 18, in the semiconductor device according to some embodiments, the upper surface of the first source/drain contact 180 corresponding to a portion that is not connected to the wiring structure 205 may be lower than the upper surface of the first gate capping pattern 145.

The upper surface of the first source/drain contact 180 corresponding to a portion connected to the wiring structure 205 may be higher than the upper surface of the first source/drain contact 180 corresponding to a portion that is not connected to the wiring structure 205.

Referring to FIG. 19, in the semiconductor device, according to some embodiments, the first source/drain contact 180 includes a lower source/drain contact 181 and an upper source/drain contact 182.

The upper source/drain contact 182 may be disposed in a portion connected to the wiring structure 205. On the other hand, the upper source/drain contact 182 may not be disposed in a portion that is not connected to the wiring structure 205.

The wiring line 207 may be connected to the first source/drain contact 180 without a wiring via (206 of FIG. 2). The wiring structure 205 may not include the wiring via (206 of FIG. 2).

Each of the lower source/drain contact 181 and the upper source/drain contact 182 is shown as a single layer, but this is only for convenience of description, and the present disclosure is not limited thereto. For example, each of the lower source/drain contact 181 and the upper source/drain contact 182 may include at least one of a metal, a metal alloy, a conductive metal nitride, a conductive metal carbide, a conductive metal oxide, a conductive metal carbonitride, or a two-dimensional (2D) material.

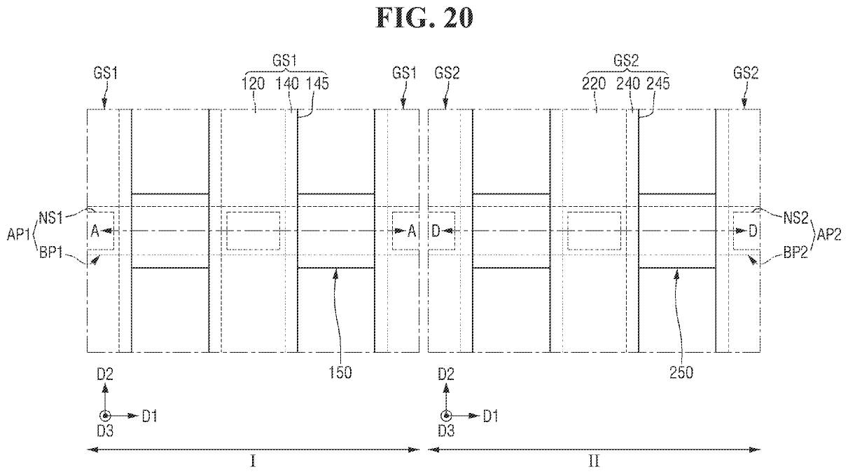

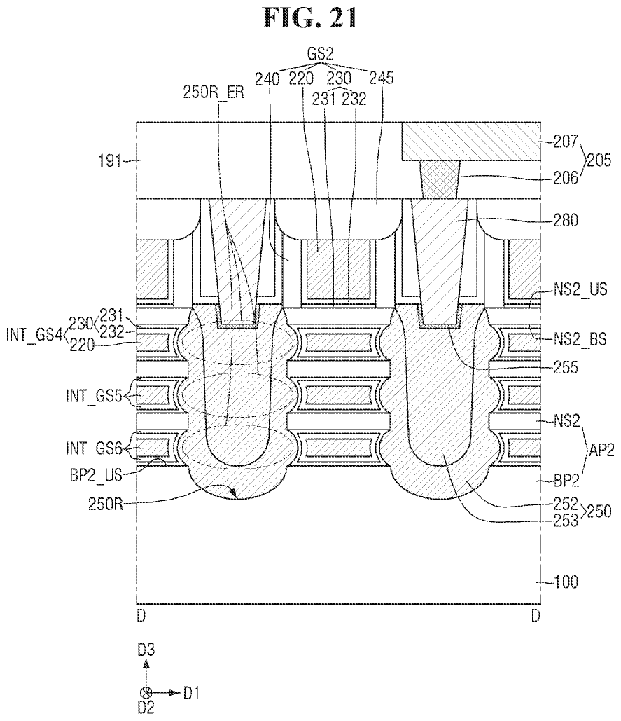

FIGS. 20 and 21 illustrate a semiconductor memory device according to some embodiments. FIG. 20 is an example plan view illustrating a semiconductor device according to some embodiments. FIG. 21 is a cross-sectional view taken along line D-D of FIG. 20.

A cross-sectional view taken along line A-A of FIG. 20 may be the same as one of FIGS. 2, 14 and 16. In addition, the description of a first region I of FIG. 20 may be substantially the same as that made with reference to FIGS. 1 to 19. Therefore, the following description will be based on the description of a second region II of FIG. 20.

Referring to FIGS. 20 and 21, the semiconductor device, according to some embodiments, may include a first active pattern AP1, a plurality of first gate electrodes 120, a second active pattern AP2, a plurality of second gate electrodes 220, a first source/drain pattern 150 and a second source/drain pattern 250.

The substrate 100 may include a first region I and a second region II. In one embodiment, the first region I may be a region in which an NMOS is formed, and the second region II may be a region in which a PMOS is formed. For another example, the first region I may be a region in which a PMOS is formed, and the second region II may be a region in which an NMOS is formed.

The first active pattern AP1, the plurality of first gate electrodes 120 and the first source/drain pattern 150 are disposed in the first region I of the substrate 100. The second active pattern AP2, the plurality of second gate electrodes 220 and the second source/drain pattern 250 are disposed in the second region II of the substrate 100.

The second active pattern AP2 may include a second lower pattern BP2 and a plurality of second sheet patterns NS2. The second lower pattern BP2 may be protruded from the substrate 100. The second lower pattern BP2 may be extended along in the first direction D1. The plurality of second sheet patterns NS2 may be disposed on the second lower pattern BP2. The plurality of second sheet patterns NS2 may be spaced apart from the second lower pattern BP2 in the third direction D3.

Each of the second lower pattern BP2 and the second sheet pattern NS2 may include one of silicon or germanium, which is an elemental semiconductor material, a Group IV-IV compound semiconductor or a Group III-V compound semiconductor. For example, the second lower pattern BP2 may be made of a semiconductor material. An upper surface BP2_US of the second lower pattern may be made of a semiconductor material.

In the semiconductor device, according to some embodiments, the second lower pattern BP2 may be a silicon lower pattern that includes silicon, and the second sheet pattern NS2 may be a silicon sheet pattern that includes silicon.

A plurality of second gate structures GS2 may be disposed on the substrate 100. Each of the second gate structures GS2 may be extended in the second direction D2. The second gate structures GS2 adjacent to each other may be spaced apart from each other in the first direction D1.

The second gate structure GS2 may be disposed on the second active pattern AP2. The second gate structure GS2 and the second active pattern AP2 may be intersected or crossed each other. The second gate structure GS2 and the second lower pattern BP2 may be intersected or crossed each other. The second gate structure GS2 may surround each of the second sheet patterns NS2.

In one embodiment, the second gate structure GS2 may include a second gate electrode 220, a second gate insulating layer 230, a second gate spacer 240 and a second gate capping pattern 245.

The second gate structure GS2 may include a plurality of inner gate structures INT_GS4, INT_GS5 and INT_GS6 disposed between the second sheet patterns NS2 adjacent to each other in the third direction D3 and between the second lower pattern BP2 and the second sheet pattern NS2. The inner gate structures INT_GS4, INT_GS5 and INT_GS6 are in contact with the upper surface BP2_US of the second lower pattern, an upper surface NS2_US of the second sheet pattern and a bottom surface NS2_BS of the second sheet pattern. The inner gate structures INT_GS4, INT_GS5 and INT_GS6 may be in contact with the second source/drain pattern 250 that will be described later.

The second gate structure GS2 may include a fourth inner gate structure INT_GS4, a fifth inner gate structure INT_GS5 and a sixth inner gate structure INT_GS6. The fourth inner gate structure INT_GS4, the fifth inner gate structure INT_GS5 and the sixth inner gate structure INT_GS6 may be sequentially disposed on the second lower pattern BP2.

The inner gate structures INT_GS4, INT_GS5 and INT_GS6 include a second gate electrode 220 and a second gate insulating layer 230, which are disposed between the second sheet patterns NS2 adjacent to each other and between the second lower pattern BP2 and the second sheet pattern NS2.

The second gate spacer 240 may be disposed on sidewalls of the second gate electrode 220. The second gate spacer 240 may not be disposed between the second lower pattern BP2 and the second sheet pattern NS2 and between the second sheet patterns NS2 adjacent to each other in the third direction D3.

The second gate insulating layer 230 may include a second gate interface insulating layer 231 and a second gate high dielectric constant insulating layer 232. The second gate high dielectric constant insulating layer 232 may be disposed between the second gate interface insulating layer 231 and the second gate electrode 220.

The other description of the second gate electrode 220, the second gate insulating layer 230, the second gate spacer 240 and the second gate capping pattern 245 are substantially the same as that of the first gate electrode 120, the first gate insulating layer 130, the first gate spacer 140 and the first gate capping pattern 145, and thus will be omitted.

The second source/drain pattern 250 may be formed on the second active pattern AP2. The second source/drain pattern 250 may be formed on the second lower pattern BP2. The second source/drain pattern 250 may be connected to the second sheet pattern NS2.

The second source/drain pattern 250 may be disposed on a side of the second gate structure GS2. The second source/drain pattern 250 may be disposed between the second gate structures GS2 adjacent to each other in the first direction D1. In one embodiment, the second source/drain pattern 250 may be disposed on both sides of the second gate structure GS2. In one embodiment, the second source/drain pattern 250 may be disposed on one side of the second gate structure GS2, and may not be disposed on the other side of the second gate structure GS2.

The second source/drain pattern 250 may be included in a source/drain of a transistor that uses the second sheet pattern NS2 as a channel region.

The second source/drain pattern 250 may be disposed in a second source/drain recess 250R. A bottom surface of the second source/drain recess 250R is defined by the second lower pattern BP2. A sidewall of the second source/drain recess 250R may be defined by the second sheet pattern NS2 and the inner gate structures INT_GS4, INT_GS5 and INT GS6.

The sidewall of the second source/drain recess 250R may have a wavy shape. The second source/drain recess 250R may include a plurality of width extension regions 250R_ER. The width extension region 250R_ER of each second source/drain recess may be defined above the upper surface BP2_US of the second lower pattern.

In one embodiment, the sidewall of the second source/drain recess 250R may have a shape similar to that of the first source/drain recess 150R shown in FIGS. 14 and 15.

The second source/drain pattern 250 may include a third epitaxial region 252 and a fourth epitaxial region 253. Unlike the first source/drain pattern 150, the second source/drain pattern 250 may not include the insertion epitaxial region (151 of FIG. 2).

The third epitaxial region 252 may be continuously formed along the second source/drain recess 250R. The third epitaxial region 252 may be extended along the sidewall of the second source/drain recess 250R and the bottom surface of the second source/drain recess 250R. The third epitaxial region 252 may be in contact with the second gate insulating layer 230 of each of the inner gate structures INT_GS4, INT_GS5 and INT_GS6.

The fourth epitaxial region 253 may be disposed on the third epitaxial region 252. The fourth epitaxial region 253 may fill the second source/drain recess 250R.

When the second active pattern AP2 is disposed in the region in which the PMOS is formed, each of the third epitaxial region 252 and the fourth epitaxial region 253 may include silicon-germanium. Each of the third epitaxial region 252 and the fourth epitaxial region 253 may include a silicon-germanium film. Each of the third epitaxial region 252 and the fourth epitaxial region 253 may include p-type doped impurities.

When the second active pattern AP2 is disposed in the region in which the NMOS is formed, each of the third epitaxial region 252 and the fourth epitaxial region 253 may include silicon. Each of the third epitaxial region 252 and the fourth epitaxial region 253 may include a silicon film. Each of the third epitaxial region 252 and the fourth epitaxial region 253 may include n-type doped impurities.

The second source/drain contact 280 is disposed on the second source/drain pattern 250. The second source/drain contact 280 is connected to the second source/drain pattern 250. The second source/drain contact 280 may be connected to the second source/drain pattern 250 by passing through the first interlayer insulating layer 190 and the source/drain etch stop layer 185.

A second metal silicide layer 255 may be further disposed between the second source/drain contact 280 and the second source/drain pattern 250.

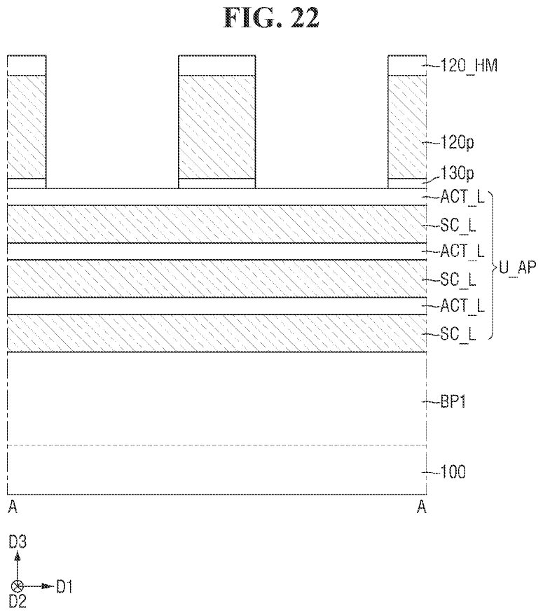

FIGS. 22 to 28 illustrate intermediate steps to describe a method for fabricating a semiconductor memory device according to some embodiments. FIGS. 22 to 28 illustrate cross-sectional views taken along line A-A of FIG. 1.

Referring to FIG. 22, the first lower pattern BP1 and an upper pattern structure U_AP may be formed on the substrate 100.

The upper pattern structure U_AP may be disposed on the first lower pattern BP1. The upper pattern structure U_AP may include a plurality of sacrificial patterns SC_L and a plurality of active patterns ACT_L, which are alternately stacked on the first lower pattern BP1.

For example, the sacrificial pattern SC_L may include a silicon-germanium film. The active pattern ACT_L may include a silicon film.

Subsequently, a dummy gate insulating layer 130p, a dummy gate electrode 120p and a dummy gate capping layer 120_HM may be formed on the upper pattern structure U_AP. The dummy gate insulating layer 130p may include, for example, silicon oxide, but is not limited thereto. The dummy gate electrode 120p may include, for example, polysilicon, but is not limited thereto. The dummy gate capping layer 120_HM may include, for example, silicon nitride, but is not limited thereto.

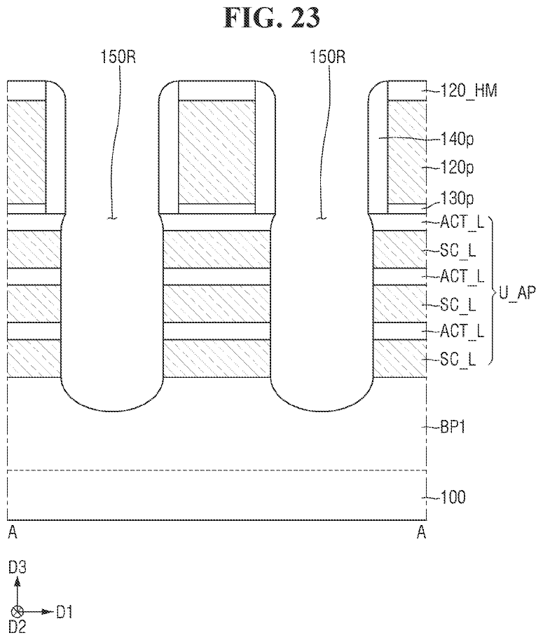

Referring to FIG. 23, a pre-gate spacer 140p may be formed on a sidewall of the dummy gate electrode 120p.

The first source/drain recess 150R may be formed in the upper pattern structure U_AP by using the dummy gate electrode 120p as a mask.

In one embodiment, the first source/drain recess 150R may be formed while the pre-gate spacer 140p is being formed. For another example, after the pre-gate spacer 140p is formed, the first source/drain recess 150R may be formed.

A portion of the first source/drain recess 150R may be formed in the first lower pattern BP1. A bottom surface of the first source/drain recess 150R may be defined by the first lower pattern BP1.

In FIG. 23, a width of the first source/drain recess 150R in the first direction D1 may be increased and then reduced as the first source/drain recess 150R becomes far away from the first lower pattern BP1.

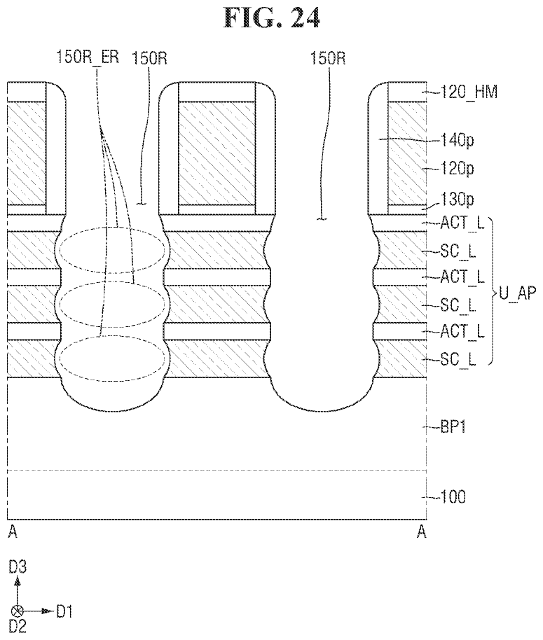

Referring to FIGS. 23 and 24, after the first source/drain recess 150R is formed, the sacrificial pattern SC_L may be additionally etched so that the width extension region 150R_ER of the first source/drain recess may be formed.

The first source/drain recess 150R may include a plurality of width extension regions 150R_ER. The sidewall of the first source/drain recess 150R may have a wavy shape. However, the method for fabricating the first source/drain recess 150R including the plurality of width extension regions 150R_ER is not limited to the aforementioned example.

The following fabricating method will be described as being performed using the first source/drain recess 150R shown in FIG. 24.

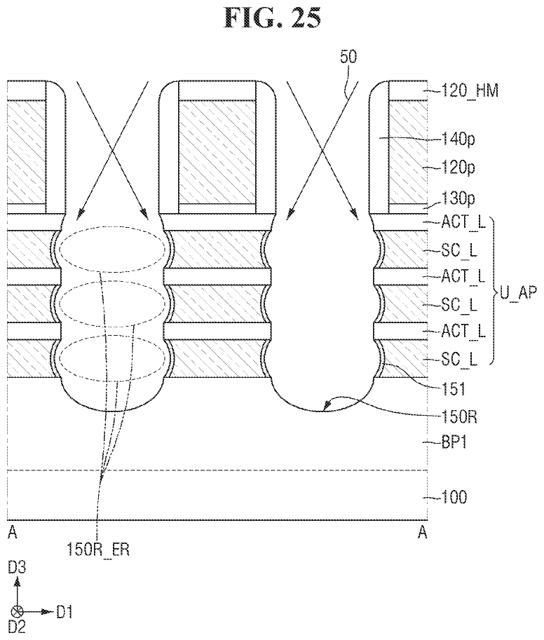

Referring to FIG. 25, the insertion epitaxial region 151 may be formed using a selective treatment process 50.

The insertion epitaxial region 151 may be formed between the first lower pattern BP1 and the active pattern ACT_L and between the active patterns ACT_L adjacent to each other in the third direction D3. For example, the selective treatment process 50 may be a selective ion implantation process. In one embodiment, the insertion epitaxial region 151 may be formed by selectively injecting impurities into the sacrificial pattern SC_L.

In one embodiment, the insertion insulating pattern (154 of FIG. 16) may be formed between the first lower pattern BP1 and the active pattern ACT_L and between the active patterns ACT_L adjacent to each other in the third direction D3. The selective treatment process 50 may be, for example, a selective surface treatment process. The insertion insulating pattern (154 of FIG. 16) may be formed by selectively surface-treating the sacrificial pattern SC_L.

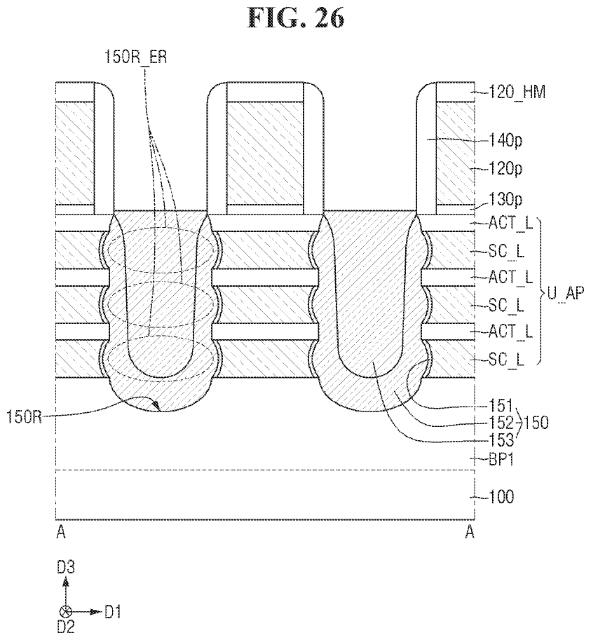

Referring to FIG. 26, the first epitaxial region 152 and the second epitaxial region 153 may be formed in the first source/drain recess 150R.

Therefore, the first source/drain pattern 150 may be formed in the first source/drain recess 150R. The first epitaxial region 152 is in contact with the insertion epitaxial region 151 and the active pattern ACT_L.

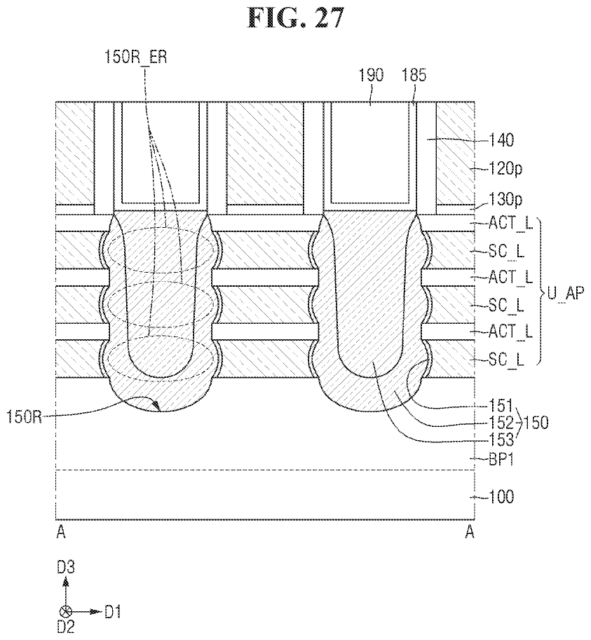

Referring to FIG. 27, the source/drain etch stop layer 185 and the first interlayer insulating layer 190 are sequentially formed on the first source/drain pattern 150.

Subsequently, a portion of the first interlayer insulating layer 190, a portion of the source/drain etch stop layer 185, and the dummy gate capping layer 120_HM are removed to expose an upper surface of the dummy gate electrode 120p. While the upper surface of the dummy gate electrode 120p is being exposed, the first gate spacer 140 may be formed.

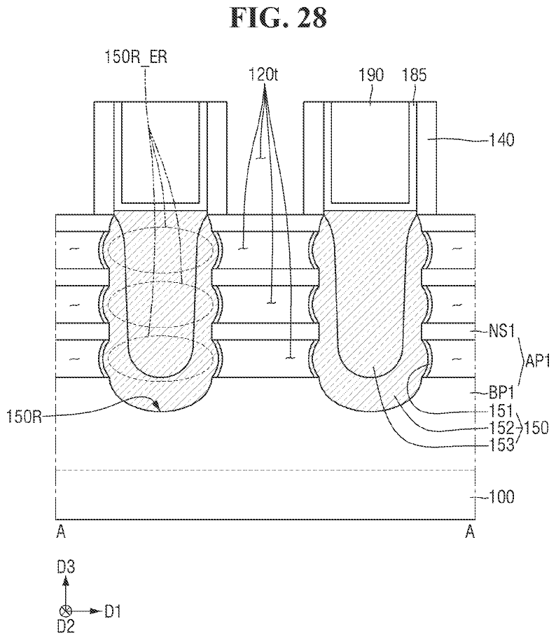

Referring to FIGS. 27 and 28, the dummy gate insulating layer 130p and the dummy gate electrode 120p may be removed to expose the upper pattern structure U_AP between the first gate spacers 140.

Subsequently, the sacrificial pattern SC_L may be removed to form the first sheet pattern NS1. The first sheet pattern NS1 is connected to the first source/drain pattern 150. Therefore, the first active pattern AP1, which includes the first lower pattern BP1 and the first sheet pattern NS1, is formed.

In addition, the sacrificial pattern SC_L is removed so that a gate trench 120t is formed between the first gate spacers 140. When the sacrificial pattern SC_L is removed, a portion of the first source/drain pattern 150 may be exposed.

The insertion epitaxial region 151 may have an etch selectivity with respect to the sacrificial pattern SC_L. While the sacrificial pattern SC_L is being removed, the insertion epitaxial region 151 may not be removed. As the insertion epitaxial region 151 remains while the sacrificial pattern SC_L is being removed, the first epitaxial region 152 is not exposed. That is, the first epitaxial region 152 and the second epitaxial region 153 are not etched by a process of removing the sacrificial pattern SC_L. While the sacrificial pattern SC_L is being removed, the insertion epitaxial region 151 may prevent the first epitaxial region 152 and the second epitaxial region 153 from being etched.

Then, referring to FIG. 2, the first gate insulating layer 130 and the first gate electrode 120 may be formed in the gate trench 120t. In addition, the first gate capping pattern 145 may be formed.

In concluding the detailed description, those skilled in the art will appreciate that many variations and modifications may be made to the preferred embodiments without substantially departing from the principles of the disclosure. Therefore, the disclosed preferred embodiments of the invention are used in a generic and descriptive sense only and not for purposes of limitation.

What is claimed is:

1. A semiconductor device comprising:
an active pattem comprising a lower pattern and a plurality of sheet pattems spaced apart from the lower pattern in a first direction;
a plurality of gate structures being spaced apart from each other in a second direction on the lower pattern, wherein each of the plurality of gate structures comprises a gate electrode and a gate insulating layer;
a source/drain recess between the gate structures adjacent to each other; and
a source/drain pattern filling the source/drain recess,
wherein the source/drain pattern comprises:
a first epitaxial region extended along a sidewall and a bottom surface of the source/drain recess,
a second epitaxial region on the first epitaxial region, and
a plurality of insertion epitaxial regions that are in contact with the first epitaxial region,
wherein the respective insertion epitaxial regions are spaced apart from each other and comprise silicon germanium, and
wherein the first epitaxial region is disposed between the second epitaxial region and the insertion epitaxial region.

2. The semiconductor device of claim 1, wherein a germanium fraction of the insertion epitaxial region is greater than that of the first epitaxial region.

3. The semiconductor device of claim 2, wherein each of the first epitaxial region and the second epitaxial region comprises silicon.

4. The semiconductor device of claim 2, wherein each of the first epitaxial region and the second epitaxial region comprises silicon germanium.

5. The semiconductor device of claim 4, wherein a germanium fraction of the second epitaxial region is greater than that of the first epitaxial region.

6. The semiconductor device of claim 1, wherein the plurality of insertion epitaxial regions comprises a first insertion epitaxial region and a second insertion epitaxial region, which are closest to each other in the first direction, and
wherein the first insertion epitaxial region is not in contact with the second insertion epitaxial region.

7. The semiconductor device of claim 1, wherein the plurality of sheet patterns comprises a first sheet pattern and a second sheet pattern, which are closest to each other in the first direction,
wherein the first sheet pattern and the second sheet pattem comprise an upper surface and a bottom surface, which are opposite to each other in the first direction,
wherein the upper surface of the first sheet pattern faces the bottom surface of the second sheet pattem, and
wherein the insertion epitaxial region is continuously formed from the upper surface of the first sheet pattern to the bottom surface of the second sheet pattem.

8. The semiconductor device of claim 1, wherein the insertion epitaxial region comprises an inner side that is in contact with the first epitaxial region, and
wherein the inner side of the insertion epitaxial region has a concave shape.

9. The semiconductor device of claim 1, wherein each of the insertion epitaxial regions comprises impurities, and
wherein the impurities comprise at least one of arsenic (As), boron (B), or carbon (C).

10. The semiconductor device of claim 1, wherein the gate structure comprises an inner gate structure disposed between the lower pattern and the sheet pattern and between adjacent sheet pattems, and
wherein the insertion epitaxial region is in contact with the gate insulating layer of the inner gate structure.

11. The semiconductor device of claim 1, wherein the source/drain recess comprises a plurality of width extension regions, and
wherein a width of each of the width extension regions in the first direction is increased and then reduced as each of the width extension regions becomes far away from the upper surface of the lower pattem.

12. A semiconductor device comprising:
an active pattem comprising a lower pattern and a plurality of sheet pattems spaced apart from the lower pattern in a first direction;
a plurality of gate structures being spaced apart from each other in a second direction on the lower pattem, wherein each of the plurality of gate structures comprises a gate electrode and a gate insulating layer;
a source/drain recess between the gate structures adjacent to each other; and
a source/drain pattern filling the source/drain recess,
wherein the gate structure comprises an inner gate structure between the lower pattern and the sheet pattern and between the sheet pattems adjacent to each other,
wherein the source/drain pattern comprises:
a plurality of insertion epitaxial regions, and
a first epitaxial region that is in contact with each of the insertion epitaxial regions and is extended along a sidewall and a bottom surface of the source/drain recess, and
wherein the plurality of insertion epitaxial regions are disposed between the lower pattem and the sheet pattern and between the sheet patterns adjacent to each other in the first direction and are in contact with the gate insulating layer of the inner gate structure.

13. The semiconductor device of claim 12, wherein each of the insertion epitaxial regions comprises silicon germanium.

14. The semiconductor device of claim 13, wherein each of the insertion epitaxial regions comprises impurities, and
wherein the impurities comprise at least one of arsenic (As), boron (B), or carbon (C).

15. The semiconductor device of claim 13, wherein the first epitaxial region comprises silicon.

16. The semiconductor device of claim 13, wherein the first epitaxial region comprises silicon germanium, and
wherein a germanium fraction of the first epitaxial region is different from that of the insertion epitaxial region.

17. The semiconductor device of claim 12, wherein the first epitaxial region is in contact with each of the sheet patterns, and
wherein the first epitaxial region is not in contact with the gate insulating layer of the inner gate structure.

18. A semiconductor device comprising:
an active pattern comprising a lower pattern and a plurality of sheet patterns spaced apart from the lower pattern in a first direction:
a plurality of gate structures being spaced apart from each other in a second direction on the lower pattern, wherein each of the plurality of gate structures comprises a gate electrode and a gate insulating layer:
a source/drain recess between the gate structures adjacent to each other, wherein the source/drain recess comprises a plurality of width extension regions: and
a source/drain pattern filling the source/drain recess,
wherein the gate structure comprises an inner gate structure disposed between the lower pattern and the sheet pattern and between the sheet patterns adjacent to each other,
wherein a width of each of the width extension regions in the first direction is increased and then reduced as each of the width extension regions becomes far away from an upper surface of the lower pattern,
wherein a point at which a width of the width extension region in a second direction is maximum is positioned between the lower pattern and the sheet pattern and between the sheet patterns adjacent to each other in the first direction,
wherein the source/drain pattern comprises:
a plurality of insertion epitaxial regions that are in contact with the gate insulating layer of the inner gate structure and include silicon germanium doped with arsenic (As),
a first epitaxial region that is in contact with each of the insertion epitaxial regions and each of the sheet patterns, including silicon, and
a second epitaxial region disposed on the first epitaxial region, including silicon doped with phosphorus (P).

19. The semiconductor device of claim 18, wherein the plurality of sheet patterns comprises a first sheet pattern and a second sheet pattern, which are closest to each other in the first direction,
wherein the first sheet pattern and the second sheet pattern comprise an upper surface and a bottom surface, which are opposite to each other in the first direction,
wherein the upper surface of the first sheet pattern faces the bottom surface of the second sheet pattern, and
wherein the insertion epitaxial region is continuously extended from the upper surface of the first sheet pattern to the bottom surface of the second sheet pattern.

20. The semiconductor device of claim 18, wherein the first epitaxial region is not in contact with the gate insulating layer of the inner gate structure.
